(19) United States
(12) Patent Application Publication
(10) Pub. No.: US 2025/0208583 A1
(43) Pub. Date: Jun. 26, 2025

(54) DEVICE FOR DETERMINING THE POSITION OF A HAND OF A WATCH

(71) Applicant: ETA SA Manufacture Horlogere Suisse, Grenchen (CH)

(72) Inventors: Dominique DUBUGNON, Saint-Prex (CH); Pierpasquale TORTORA, Neuchâtel (CH); Sylvain HUOT-MARCHAND, Eschert (CH); Raphael COURVOISIER, Corcelles (CH)

(73) Assignee: ETA SA Manufacture Horlogere Suisse, Grenchen (CH)

(21) Appl. No.: 18/919,700

(22) Filed: Oct. 18, 2024

(30) Foreign Application Priority Data
Dec. 22, 2023 (EP) 23220049.3

(51) Int. Cl. G04D 7/00; G04B 19/04; G04C 10/02

(52) U.S. Cl. CPC G04D 7/004; G04B 19/04; G04C 10/02

(57) ABSTRACT

A dial (2a, 2b) of a watch (1) including a device (3) for determining the position of at least one hand (24a, 24b) of this watch (1), such a dial (2a, 2b) having a visible face (20a) and a hidden face (20b), the dial (2a, 2b) being formed by a stack (9a, 9b) of thin layers (10, 11, 12, 13, 14) of material extending between these two faces (20a, 20b), each of the layers (10, 11, 12, 13, 14) comprising one or more of the functional elements included in the determination device (3): at least one light-detecting element (23), at least a first light source (4a) and at least a second light source (4b), a stand-alone power supply unit (21) comprising a photovoltaic module (5), and a control unit (7) for managing the operation of each light source (4a, 4b) and of the at least one light-detecting element (23).

### CROSS REFERENCE TO RELATED APPLICATION

This application claims priority to European Patent Application No. 23220049.3 filed Dec. 22, 2023, the entire contents of which are incorporated herein by reference.

### TECHNICAL FIELD OF THE INVENTION

The present invention relates to a watch comprising a dial provided with a device for determining the position of at least one hand of this watch, such a device being autonomous.

### TECHNOLOGICAL BACKGROUND

Prior art documents describe electromechanical watches with hands, in which watches the hour hand and minute hand displaying the current time are driven by the gear trains of a mechanism of a horological movement. In this context, the operation of the mechanism can be disrupted by impacts to the watch, the presence of electromagnetic fields or other external disturbances. As a result, although the watch's internal clock provides an accurate indication of the current time, the hour and minute hands provide a distorted indication of this current time due to the effect of the external disturbance to the watch. It may therefore be necessary to resynchronise the position of the hour and minute hands.

In this context, it is understood that there is a need to find a solution that overcomes the drawbacks of the prior art.

### SUMMARY OF THE INVENTION

The aim of the invention is to overcome these drawbacks by proposing a watch provided with a dial comprising a device for determining the position of at least one hand, which device is autonomous and whose efficiency remains constant over time.

One aspect of the invention relates to a watch dial comprising a device for determining the position of at least one hand of this watch, such a dial comprising a visible face and a hidden face, said dial being formed by a stack of thin layers of material extending between these two faces, each of said layers comprising one or more of the functional elements included in said determination device:
a. at least one light-detecting element,
b. at least a first light source and at least a second light source,
c. a stand-alone power supply unit comprising a photovoltaic module, and
d. a control unit for managing the operation of each light source and of said at least one light-detecting element.

In other embodiments:
a. the dial comprising a through-hole configured to receive an arbor intended to carry said at least one hand of the watch;
b. the stack of thin layers of material consists of a first layer provided with the visible face of the dial and comprising said at least one light-detecting element and the first and second light sources;
c. the stack of thin layers includes a second layer comprising the photovoltaic module;
d. said at least one first light source and said at least one light-detecting element are arranged so that a light beam emitted by said at least one first light source is reflected by said at least one hand towards said at least one light-detecting element;
e. said at least one first light source is configured to emit a light beam towards a reflective area of said at least one hand, said reflective area being configured to reflect this light beam towards said at least one light-detecting element;
f. the reflective area comprises an inclined reflective surface which is formed in a lower face of said at least one hand;
g. the reflective area comprises a diffraction grating formed in a lower face of said at least one hand, said grating being configured to reflect a light beam towards said at least one light-detecting element;
h. said at least one first light source is a vertical-cavity surface-emitting laser source;
i. said at least one second light source is capable of generating a visual message according to the determined position of said at least one hand;
j. said first layer is configured such that light radiation, in particular solar radiation and light radiation emitted by the first and second light sources, can fully or partially pass therethrough;
k. the second layer comprises a substrate on which the photovoltaic module is printed;
l. said photovoltaic module is arranged on an active area of said second layer, said area being configured to receive light rays originating from the first layer of the stack of thin layers;
m. the stack of thin layers includes a third layer comprising an electrical energy accumulator constituting the stand-alone power supply unit;
n. the third layer comprises a substrate on which the electrical energy accumulator is printed;
o. the stack of thin layers comprises a fourth layer forming the hidden face of the dial comprising the control unit;
p. the stack of thin layers comprises a third layer comprising the hidden face of the dial comprising the control unit and an electrical energy accumulator constituting the stand-alone power supply unit;
q. the first layer is rigid compared to the other layers in the stack, which are flexible.

Another aspect of the invention relates to a watch comprising such a dial.

Advantageously, the watch comprises a mechanical or electromechanical horological movement.

### BRIEF DESCRIPTION OF THE FIGURES

The purposes, advantages and features of the watch according to the invention will appear more clearly in the following description which is given on the basis of at least one non-limiting embodiment shown by way of the drawings, in which:

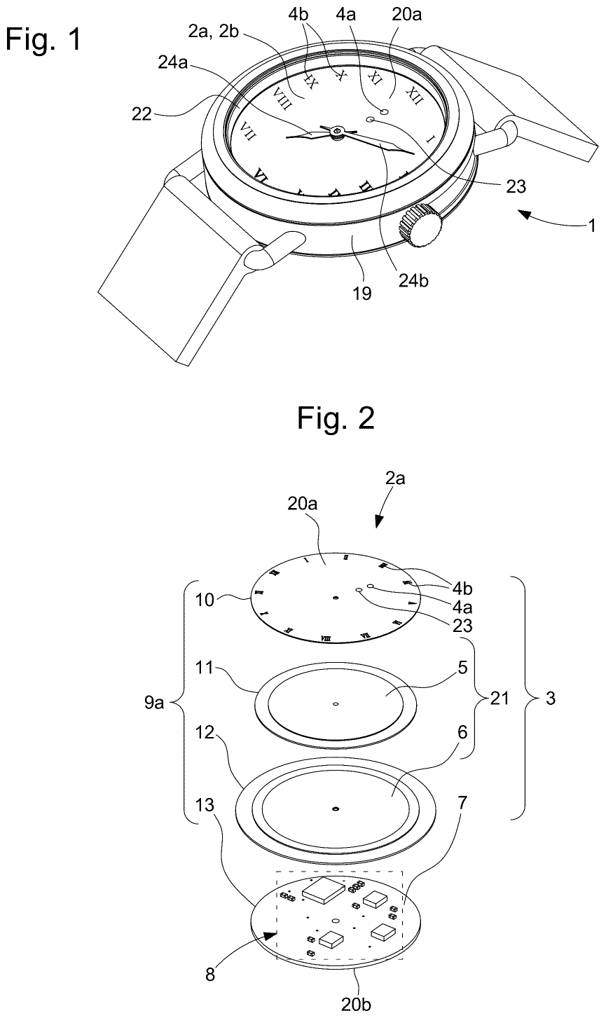

a. FIG. 1 shows a perspective view of a watch comprising a dial provided with an autonomous device for determining the position of at least one hand of the watch, according to embodiments of the invention;

b. FIG. 2 shows an exploded view of a first alternative embodiment of the dial formed by a stack of four superimposed layers, said layers each comprising one or more component elements of the determination device, according to a first implementation of the invention;

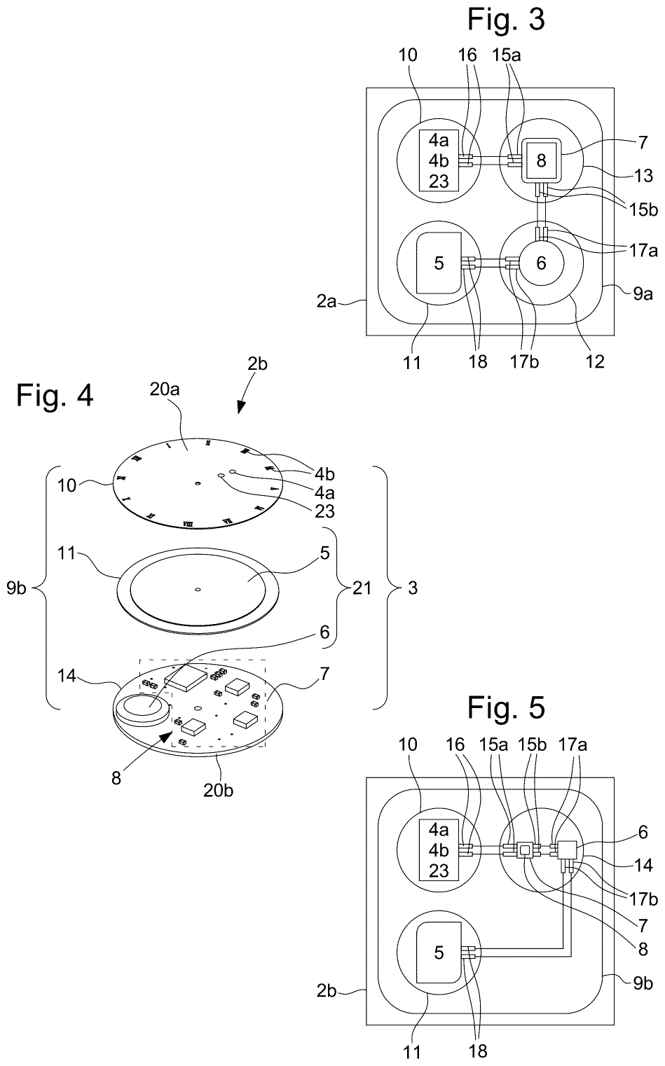

c. FIG. 3 diagrammatically shows this first alternative embodiment of the dial provided with the autonomous determination device according to the first embodiment of the invention;

d. FIG. 4 shows an exploded view of a second alternative embodiment of the dial formed by a stack of three superimposed layers, said layers each comprising one or more component elements of the determination device, according to a second implementation of the invention;

e. FIG. 5 diagrammatically shows this second alternative embodiment of the dial provided with the autonomous determination device, according to the second embodiment of the invention, and

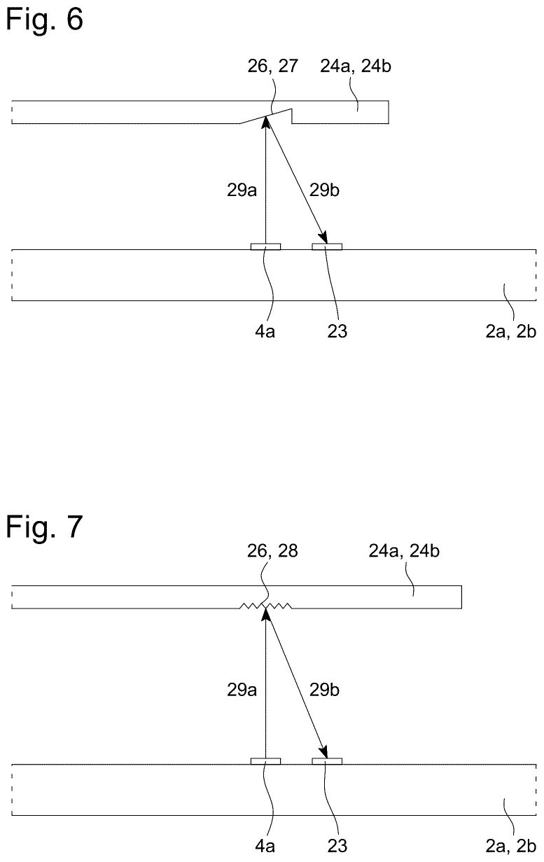

f. FIGS. 6 and 7 diagrammatically show the dial and a hand of the watch, the hand comprising a lower face provided with an area reflecting a light beam emitted by a first light source towards a light-detecting element, according to the embodiments of the invention.

### DETAILED DESCRIPTION OF THE INVENTION

FIG. 1 diagrammatically shows a watch 1 comprising a case 19 with a middle to which a back and a crystal 22 are attached, a set of components forming a horological movement, and a dial 2a, 2b arranged between the horological movement and the crystal 22.

In a manner known to a person skilled in the art, the horological movement drives a set of hands comprising an hour hand 24a, a minute hand 24b and optionally a seconds hand. To this end, the dial 2a, 2b comprises a through-hole receiving the arbor 25 of the hands. These hands 24a, 24b each have a reflective lower face arranged facing the dial 2a, 2b. This lower face is wholly or partially reflective. In particular, with reference to FIGS. 6 and 7, this lower face comprises a reflective area 26 including an inclined surface 27 or a diffraction grating 28.

Such a dial 2a, 2b further comprises two faces 20a, 20b:
a. a so-called visible face 20a which is visible from the outside of the watch 1, also referred to as the “visible part” or “visible upper part” of this dial 2a, 2b, and
b. a so-called hidden face 20b arranged facing the horological movement in an enclosure of the case 19 of the watch 1, this face 20b being otherwise referred to as the “hidden part” or “hidden lower part” of this dial 2a, 2b.

Such a visible face 20a can comprise, in a non-limitative and non-exhaustive manner, at least one graphic representation such as:
a. a reference (or display) element such as, for example, a numeral, an index, a line or even a dot contributing, with or without the hands, to the display of a piece of horological information/a horological measurement or a piece of physical information/a physical measurement taken by a sensor or the like included in the movement;
b. an inscription, a pattern, a text, or a logo, etc.

This visible face 20a and this hidden face 20b are substantially flat and/or parallel and/or opposite each other. They are also connected to each other by a peripheral wall of this dial 2a, 2b.

It should also be noted that in the embodiments illustrated in FIGS. 1 to 7, the dial 2a, 2b preferably has a circular shape. It is understood that the invention can also be implemented for dials 2a, 2b having other shapes such as, for example, a triangular shape or a shape similar to that of a quadrilateral.

In the embodiments of the invention, the horological movement is a mechanical movement. Alternatively, this movement can be an electromechanical movement. In the description below, reference will be made to a mechanical watch when its movement is mechanical and to an electromechanical watch when its movement is electromechanical.

With reference to FIGS. 2 and 4, such a dial 2a, 2b comprises an autonomous device 3 for determining a position of at least one hand 24a, 24b of the watch 1. This determination device 3 comprises its own electrical power supply means as will be described hereafter. Such a determination device 3 is said to be autonomous in particular relative to the movement of the watch 1 and in particular relative to the power source of this movement, for example when this source is an electrical power supply as in an electromechanical movement. In these circumstances, it is understood that the power used by this determination device 3 is not to the detriment of the autonomy of the movement.

In this context, the dial 2a, 2b can be removably mounted in the watch 1, regardless of the type of watch 1. The only condition to be met is that the dial 2a, 2b includes this determination device 3 which is thus autonomous as regards the movement of the watch 1. This dial 2a, 2b is also referred to as an “autonomous dial” because it is not connected electrically to the movement of the watch 1. This dial 2a, 2b can be considered as a separate part attached to the watch 1.

This determination device 3 included in this dial 2a, 2b, comprises light sources 4a, 4b, a stand-alone power supply unit 21, at least one light-detecting element 23 and a control unit 7.

These light sources 4a, 4b include at least a first light source 4a which is used to assess the position of at least one hand 24a, 24b of the watch 1 by cooperating with said at least one detecting element 23. As will be seen below, this first light source 4a and the detecting element 23 are arranged under or on the visible face 20a of the dial 2a, 2b. In this configuration, this first light source 4a is then able to emit a light beam 29a towards the hand 24a, 24b which moves above the visible face 20a, said hand 24a, 24b being able to reflect this beam 29a, into a light beam 29b, towards the detecting element 23. Such a first light source 4a is preferably a Vertical-Cavity Surface-Emission Laser or VCSEL.

These light sources 4a, 4b also include at least one second light source 4b which is used in particular to display a visual message relating to the determination of the position of the hand 24a, 24b. This second light source 4b preferably includes any light-emitting element selected from a non-exhaustive and non-limiting list that includes:
a Light-Emitting Capacitor or LEC;
a light-emitting diode of the LED (Light-Emitting Diode) type, OLED (Organic Light-Emitting Diode) type, AMOLED (Active-Matrix Organic Light-Emitting Diode) type or QLED (Quantum Light-emitting diode) type;
any light-emitting material activated by a local electric field;
any light-emitting material activated by an electric current;
any combination of these light-emitting elements.

It should be noted that this second light source 4b can, in certain embodiments of the invention, be a light source 4b capable of forming an area light source. This makes it possible to give the area light source a predetermined shape, typically, without this being exhaustive or limiting, a shape relating to a graphic representation of a numeral, a letter, a logo or a text. It should also be noted that this second light source 4b can produce light in any colour and/or in any direction.

In this determination device 3, the stand-alone power supply unit 21 comprises an electrical energy accumulator 6 and a photovoltaic module 5 comprising at least one photovoltaic cell, also referred to as a solar cell. This photovoltaic module 5 is connected to the electrical energy accumulator 6 via connection elements denoted by the reference numerals 17b and 18 in FIGS. 3 and 5. This photovoltaic module 5 can comprise one or more unit cells of the heterojunction or multijunction type, connected in parallel or in series. Each photovoltaic cell of this module 5 can be made, in a manner known to a person skilled in the art, from copper-, indium-, gallium- and selenium-based semiconductor materials, from cadmium telluride-based semiconductor materials, from monocrystalline gallium arsenide-based semiconductor materials, from monocrystalline or polycrystalline silicon-based semiconductor materials, or from perovskite semiconductor materials. It should be noted that these examples are not limitative and that a person skilled in the art will be able to find the type of photovoltaic cell suitable for the invention.

In this determination device 3, the control unit 7, also referred to as a microcontroller, comprises an electronic circuit 8 including hardware resources, in particular at least one processor cooperating with memory elements as well as address, data and control buses. This control unit 7 is connected to said first and second light sources 4a, 4b, to said at least one light-detecting element 23 and to the stand-alone power supply unit 21. The memory elements of this control unit 7 comprise an algorithm for managing the position of at least one hand 24a, 24b of the watch. Such an algorithm is executed by the processor of this control unit 7, taking account in particular of light intensity measurement data from said at least one light-detecting element 23 included in the determination device 3. Such an algorithm helps to:
a. determine this position,
b. generate the visual message according to the determined position of the hand 24a, 24b,
c. control said second light source 4b,
d. implement at least one function of the watch requiring the determined position of the hand.

It should be noted that the determination device 3 can comprise at least one event sensor allowing the determination of this position of the hand 24a, 24b to be refined and also contributing to displaying said visual message. This sensor can thus generate data which will then be used by this algorithm. Such data can include information relating to events detected by this sensor, said events being likely to contribute to the operation of said first and second light sources 4a, 4b. These events can include, in a non-limiting and non-exhaustive manner: the detection of a particular brightness level in the environment of the watch 1, the detection of a particular sound element or of a particular sound level, the detection of a particular visual object, or the detection of a movement made by a part of the user's body on which this watch 1 is included, etc.

In this context, the event sensor of this autonomous determination device 3 can comprise in particular and in a non-limiting and non-exhaustive manner:
a. a brightness sensor to detect the ambient brightness level;
b. a motion sensor for sensing a movement made by a part of the user's body comprising the watch 1, such as a gyroscopic and/or inertial sensor in the form of an electronic component of the gyroscopic and/or inertial electromechanical microsystem circuit type;
c. a microphone-type sound sensor, and/or
d. a photographic-type optical sensor.

Furthermore, when the determination device 3 comprises a plurality of second light sources 4b, the operation thereof can then be managed/controlled by the control unit 7 simultaneously and/or sequentially. Moreover, each second light source 4b is managed/controlled separately by this control unit 7. In this context, the management of the operation of each second light source 4b can consist, in a non-limiting and non-exhaustive manner, of carrying out the following operations: sequential switching on or off, simultaneous switching on or off of two or more second light sources 4b, flashing of one or more second light sources 4b, definition of a flashing frequency for each second light source 4b, a flashing duration for each second light source 4b, or a switching on or off duration for each second light source 4b, etc.

The memory elements of such a control unit 7 can further comprise an algorithm for managing the electrical energy accumulator 6, in particular for managing its recharging by the photovoltaic module 5 and for managing the electrical consumption of said light sources 4a, 4b and also of said at least one light-detecting element 23.

As mentioned above, the autonomous determination device 3 is thus included in the dial 2a, 2b. In this configuration, the component elements of this determination device 3, namely the first and second light sources 4a, 4b, the electrical energy accumulator 6, the photovoltaic module 5, said at least one light-detecting element 23 and the control unit 7, are included in one or more layers 10, 11, 12, 13, 14 forming this dial 2a, 2b.

With reference to FIGS. 2 to 5, this dial 2a, 2b is constituted or formed by a stack 9a, 9b of thin layers 10, 11, 12, 13 of material, these layers 10, 11, 12, 13, 14 being joined together by a joining element such as an adhesive substance so as to unify them in order to obtain a stack 9a, 9b of monolithic layers thus forming a one-piece dial 2a, 2b. This joining element can also be a clip or a screw. Such layers 10, 11, 12, 13, 14 are superimposed in the stack 9a, 9b, i.e. they are arranged one on top of the other in this dial 2a, 2b in a defined order. It should be noted that such a stack 9a, 9b of layers can also be referred to as an assembly of layers. In this stack 9a, 9b, the layers are substantially similar, having upper and lower surfaces of substantially the same area, thus helping to form the peripheral wall of the dial 2a, 2b, which has no relief.

It should be noted that these thin layers are layers that each have a micrometric thickness. More specifically, each layer can have a thickness of between 1 and 100 μm, preferably 2 μm, or more preferably 3 μm. Relative to the thickness of the dial 2a, 2b, it can be between 8 and 400 μm, preferably 6 μm, more preferably 12 μm, more preferably 100 μm, more preferably 200 μm or more preferably 300 μm.

Such a one-piece dial 2a, 2b also has the additional advantage of being able to be removably mounted in the case 19 of the watch 1, in addition to facilitating its integration in this case 19.

In a first alternative embodiment of this stack 9a illustrated in FIG. 3, it is constituted or formed by the following four successive thin layers 10, 11, 12, 13:
a. a first layer 10 forming/constituting the visible face 20a of the dial 2a including said at least one first light source 4a, said at least one second light source 4b and said at least one light-detecting element 23 of the determination device 3;
b. a second layer 11 including the photovoltaic module 5;
c. a third layer 12 including an electrical energy accumulator 6, also referred to as a rechargeable battery, and
d. a fourth layer 13 forming the hidden face 20b of the dial 2a including the control unit 7.

The first layer 10 of this stack 9a is preferably rigid or semi-rigid compared with the second, third and fourth layers 11, 12, 13 which are preferably pliable or flexible. It is understood that such a first layer 10 contributes to the structural rigidity of the stack 9a and thus of the dial 2a.

In this stack 9a, the first, second, third and fourth layers 10, 11, 12 and 13 each comprise an upper surface and a lower surface.

The first layer 10 is formed by a transparent, translucent, at least partially transparent, or at least partially translucent rigid or semi-rigid substrate. Such a substrate is made of a material with a transmittance for solar radiation, in particular ultraviolet radiation, also referred to as UVT (for “Ultra-Violet Transmission”) of between 65 and 95 percent. This transmittance is preferably 85 percent. Such a material can be transparent or translucent. This material can be, in a non-limiting and non-exhaustive manner, a polymer, glass or ceramic.

In this context, it is understood that this substrate is configured so that:
a. the light produced by the first and second light sources 4a, 4b can escape to the outside of the dial 2a, 2b and thus of the watch 1, and
b. light from the environment of the watch 1 can penetrate the dial 2a, 2b towards the photovoltaic module 5 of the determination device 3, this light comprising solar radiation when it is of natural origin.

In other words, this transparent or translucent substrate is configured to allow said light capable of supplying the photovoltaic module 5 to pass therethrough so that the latter can convert the solar energy from this radiation into electrical energy.

This first layer 10 further comprises first and second light sources 4a, 4b which are arranged in the body of the substrate.

Such an arrangement of said at least one first light source 4a in/on this substrate is configured to ensure that the light beam 29a is emitted upwards towards said at least one hand 24a, 24b. This first light source 4a can be arranged on or under the upper surface of this substrate forming the first layer 10. When arranged in the substrate, this first light source 4a is positioned in a blind cavity formed in this upper surface. In an alternative embodiment, it can be arranged in a blind cavity made in the lower face of this substrate having this upper face as its bottom. In this configuration, the light beam 29a capable of being emitted by this first light source 4a then passes through this bottom before reaching the hand 24a, 24b.

Such an arrangement of said at least one second light source 4b in this substrate is configured to ensure illumination of all or part of the visible face 20a of the dial 2a in order to participate in particular in the display of the visual message which is a function of the determined position of the hand 24a, 24b, for example, illumination of a graphic representation relating to this position such as a pattern, a numeral or a letter, and/or a graphic representation such as a reference element (or display) such as a numeral, an index, a line, a dot or illumination of one or more hands, or even illumination of all or part of the surface of the visible face of the dial 2a. In an alternative embodiment, this second light source 4b can have a predetermined shape such as the shape of a numeral, a letter, an index, a line, a dot, a logo or even a text.

This illumination can be backlighting or semi-direct illumination when the second light source 4b is arranged in a cavity defined in the substrate. More specifically, this cavity can be a blind opening made in the lower surface of this substrate. In this configuration, when the bottom of this cavity includes a graphic representation, the luminous radiation, or the light, produced by this second light source 4b can escape to the outside of the dial 2a via the visible face 20a of this dial 2a, thus allowing at least one graphic representation to be viewed in the dark. In particular, the light radiation escaping from the visible face 20a draws the outline of this graphic representation. In this context, this graphic representation included in or on the upper surface or on the lower surface of the substrate forming the first layer 10, is preferably opaque, non-translucent or non-transparent.

This illumination can be direct illumination when the second light source 4b is arranged in a cavity defined in the substrate. This cavity can be a blind opening made in the lower surface of this substrate, the bottom of which is devoid of any graphic representation. In this configuration, the luminous radiation, or light, produced by this second light source 4b can escape through the bottom of this cavity towards the outside of the dial 2a and thus through the visible face 20a of this dial 2a.

This illumination can also be direct illumination when the second light source 4b is arranged in a through-opening extending through the thickness of the substrate of the first layer 10, opening, at its two ends, respectively onto the upper and lower surfaces of this substrate. In this configuration, all or part of the second light source 4b can project from the upper surface of this substrate and thus from the first layer 10 or from the visible face 20a of the dial 2a to form a graphic representation such as an index, a number, a dot, or a line, etc.

Such illumination can also be remote illumination when said at least second light source 4b is coupled to at least one waveguide. This waveguide, also referred to as a light guide, is used to carry light from the point where it is injected into the guide to the substrate or to an area of the substrate (e.g. cavity, through-opening) close to the upper surface of this substrate. Such a light guide can be an optical fibre that allows any obstacles that can arise in the substrate to be bypassed, for example between the electroluminescent element and the region of the substrate close to the upper surface of this substrate, through which the light will escape. In this alternative embodiment, it is thus the light that is brought, via the waveguide, from the electroluminescent element to this area of the substrate to be illuminated.

In such a configuration, a first end of the waveguide is coupled to the second light source 4b and a second end of this waveguide can be arranged in:
a. a cavity which can be a blind opening made in the lower surface of the substrate of this first layer 10, or
b. a through-opening extending through the thickness of the substrate of the first layer 10 and opening, at its two ends, respectively onto the upper and lower surfaces of this substrate and thus of the first layer 10. This second end can thus project from the upper surface of the substrate or of this first layer 10 or from the visible face 20a of the dial 2a in order, for example, to form a graphic representation of this dial 2a such as, for example, a reference element such as an index, a numeral, a dot, or a line, etc.

In this context, indirect illumination can be achieved by a single second light source 4b included on the lower surface of the substrate of this first layer 10 by being coupled to a plurality of waveguides whose second ends are arranged in:
a. cavities each emitting light radiation from this second light source 4b, this radiation escaping to the outside of the dial 2a via the visible face 20a, thus allowing at least one graphic representation to be viewed in the dark. In this context, this graphic representation included in or on the visible face 20a of the dial 2a, or the upper surface of the substrate, is preferably opaque, and/or
b. through-openings projecting or not projecting from the upper surface of this substrate in order to form reference elements such as an index, line or even a dot, and each emitting light radiation from this second light source 4b.

In this first layer 10, the second light source 4b is applied/fastened to the lower surface of the substrate of this first layer 10, in a cavity or on an internal wall of a previously mentioned through-opening, by printing or evaporation.

In this first layer 10, the light-detecting element 23 is arranged in/on this substrate relative to the first light source 4a so as to be able to receive the light beam 29b reflected by the hand 24a, 24b which has been emitted by this light source 4a. This detecting element 23 can be arranged on or under the upper surface of this substrate forming the first layer 10. When arranged in the substrate, this detecting element 23 is positioned in a blind cavity formed in this upper surface. In an alternative embodiment, it can be arranged in a blind cavity made in the lower face of this substrate having this upper face as its bottom. In this configuration, the light beam 29b reflected by the hand then passes through this bottom before reaching said detecting element 23.

It should also be noted that the lower surface of this first layer 10 can be self-adhesive so that it can be assembled with the second layer 11.

In this stack 9a, the second layer 11 comprises a substrate including the photovoltaic module 5. Such a substrate is preferably flexible or pliable. The substrate of the second layer 11 can be a film on which the photovoltaic module 5 is arranged, or it can be made of a material belonging to the polymer family.

In this second layer 11, the photovoltaic module 5 extends preferentially over the whole of a so-called active area of the upper surface of this substrate. This active area is a portion of the upper surface of the substrate which is able to receive light from the lower surface of the first layer 10 of the dial 2a. This light, which has passed through all or part of the first layer 10, comes from the external environment of the dial 2a, and thus of the watch 1, in this case mainly from solar radiation when it is of natural origin.

It should be noted that the photovoltaic module 5 is applied to the upper surface of this substrate using inkjet or screen printing processes or using thermal evaporation printing processes. Reference will also be made here to a second layer 11 comprising a printed photovoltaic module 5, in particular, a photovoltaic module 5 printed on the substrate of the second layer 11.

It should be noted that once the photovoltaic module 5 has been applied to the substrate, a layer of a self-adhesive substance can be deposited on all or part of the upper surface and/or of the lower surface of the substrate. In these circumstances, the second layer 11 can be a self-adhesive layer which helps to facilitate its assembly with the other layers, in particular with the first layer 10 and/or the third layer 12 of this stack 9a.

In the stack 9a, this third layer 12 further comprises a preferably flexible or pliable substrate, including the electrical energy accumulator 6 of the autonomous determination device 3. This substrate of the third layer 12 can be a film on which the accumulator 6 is arranged. Such a substrate can be made of a material belonging to the polymer family.

This accumulator 6 can be a lithium battery or a semiconductor battery. Such a battery 6 is applied to the upper surface of this substrate using processes known in the prior art, such as:
a. printing processes on a flexible polymer substrate, when this involves a lithium battery for example, or
b. three-dimensional printing processes, for example when this involves a semi-conductor battery such as a lithium-metal semi-conductor battery.

Reference will also be made here to a third layer 12 comprising a printed electrical energy accumulator 6, in particular, an electrical energy accumulator 6 printed on the substrate of the third layer 12.

Such processes make it possible to obtain a third layer 12 comprising this accumulator 6 which is flexible and ultra-thin.

Moreover, it should be noted that once the accumulator 6 has been applied to the substrate, a layer of a self-adhesive substance can be deposited on all or part of the upper surface and/or of the lower surface of this substrate. In these circumstances, the third layer 12 can be a self-adhesive layer which helps to facilitate its assembly with the other layers, in particular with the second layer 11 and/or the fourth layer 13 of this stack 9a.

It should be noted that this accumulator 6 is used to store the electrical energy produced by the photovoltaic module 5 and to release it on demand to power the determination device 3, in particular the first and second light sources 4a, 4b and said at least one detecting element 23.

In this stack 9a, this fourth and final layer 13 forms the hidden face of the dial 2a. Such a fourth layer 13 is formed by a preferably flexible or pliable substrate, including the control unit 7. Such a substrate for the fourth layer 13 can be, for example, a flexible PCB (Printed Circuit Board) on which this control unit 7 is arranged, in particular on the upper surface of this PCB and thus of the substrate. In this context, the control unit 7 can be constructed on this upper surface of the substrate using three-dimensional printing processes or polymer printing processes.

In the second alternative embodiment, the stack 9b forming the dial 2b comprises three thin layers 10, 11, 14, joined together. It should be noted that this second alternative embodiment differs from the first alternative embodiment in that it comprises three layers 10, 11, 14 instead of four layers 10, 11, 12, 13, as in the first alternative embodiment. In this second alternative embodiment, the electrical energy accumulator 6 of the autonomous determination device 3 is now included in the third and final layer 14 of this stack 9b with the control unit 7.

Such a third and final layer 14 of this stack 9b, forming the hidden face of the dial 2b, consists of a preferably flexible or pliable substrate, on which are constructed, preferably on the upper surface of this substrate, the battery 6 and the electronic circuit 8 constituting the control unit 7. The accumulator 6 and the control unit 7 can be constructed on this upper surface of the substrate using three-dimensional printing processes or polymer printing processes. It should be noted that such a substrate can be, for example, a flexible PCB.

In summary, in this second alternative embodiment, the stack 9b comprises:
a. a first layer 10 forming the visible face 20a of the dial 2b including said first and second light sources 4a, 4b and said detecting element 23;
b. a second layer 11 including the photovoltaic module 5, and
c. the third layer 14 forming the hidden face 20b of the dial 2b including the accumulator 6 and the control unit 7.

It should be noted that in this second alternative embodiment, the first and second layers 10, 11 are similar to those of the first alternative embodiment of stack 9a.

Furthermore, with reference to FIGS. 3 and 5, the electronic circuit 8 of the control unit 7 comprises first connection elements 15a which are connected to connection elements 16 to the first and second light sources 4a, 4b and to said at least one detecting element 23 for determining the position of the hand and displaying a visual message depending on this position. This electronic circuit 8 further comprises second connection elements 15b connected to first connection elements 17a of the accumulator 6.

In a third alternative embodiment not shown, the stack forming the dial comprises two interconnected layers. It should be noted that this third alternative embodiment differs from the second alternative embodiment in that it comprises two layers instead of three layers 10, 11, 14, as in the second alternative embodiment. In this third alternative embodiment, the photovoltaic module 5 of the autonomous determination device 3 is now included in the first layer and in particular on the lower surface of the substrate forming this first layer. This photovoltaic module 5 can be applied to this lower surface of the substrate of this first layer using inkjet or screen printing processes or using thermal evaporation printing processes. It should thus be noted that this first layer is therefore similar to the first layers 11 of the first and second alternative embodiments, with the exception that in this third alternative embodiment, the first layer additionally comprises the photovoltaic module.

In the third alternative embodiment, and similarly to the second alternative embodiment, the electrical energy accumulator 6 of the autonomous determination device 3 is included in the second and final layer of this assembly with the control unit 7. Such a second layer forming the hidden face of the dial, consists of a preferably flexible or pliable substrate, on which are constructed, preferably on the upper surface of this substrate, the battery 6 and the electronic circuit 8 constituting the control unit 7. This accumulator 6 and the control unit 7 can be constructed on the upper surface of the substrate using three-dimensional printing processes or polymer printing processes. It should be noted that such a substrate can be, for example, a flexible PCB.

In summary, in this third alternative embodiment, the stack comprises:
a. a first layer forming the visible face 20a of the dial including said first and second light sources 4a, 4b, said at least one detecting element 23 and the photovoltaic module 5 of the determination device 3, and
b. a second layer forming the hidden face 20b of the dial including the accumulator 6 and the control unit 7.

Moreover, it should be noted that the event sensors of the determination device 3, mentioned above, are preferably arranged in the first layer 10 and/or the final layer 13, 14 of the stack 9a, 9b of layers and are connected to the control unit 7 of this device 3.

Thus, in this dial 2a, 2b, the determination device 3 comprises, preferably dedicated to each hand, the detecting element 23 which measures a light intensity. In a determined position of the hand 24a, 24b, the light beam 29a emitted by the first light source 4a is reflected by this hand 24a, 24b, into a light beam 29b, towards this light-detecting element 23. More specifically, this emitted light beam 29a is reflected by the reflective area 26 of the hand which is defined on its lower face. This area 26 comprises the inclined reflective surface 27 or the diffraction grating 28 which is formed in this lower face. This inclined reflective surface 27 and the diffraction grating 28 are configured to reflect such a light beam 29a towards the detecting element 23. In this configuration, the light intensity is measured by this element 23 and transmitted to the control unit, which processes and archives it. As soon as the measurement of this intensity increases abruptly as a result of the hand passing over the detecting element 23, the control unit determines the position of this hand. During this passage, the detecting element measures a light intensity resulting from the reception by this element 23 of the light beam 29b reflected by the reflective area of the hand. As the minute hand is usually positioned above the hour hand, this difference in height generates a difference in light intensity perceived by the detecting element 23. Advantageously, it is possible to identify each of the hands with a single first light source 4a and a single light-detecting element 23.

Determining the position of this hand can thus allow this dial 2a, 2b to implement various functions of this watch. For example, one function of this watch can correspond to detecting a loss of timing accuracy. This is because drive steps are lost in the case of an electromechanical movement as a result of impacts to the watch, the presence of electromagnetic fields or other external disturbances. As a result, although a watch's internal clock provides an accurate indication of the current time, the hour and minute hands provide a distorted indication of this current time, because the gears have skipped a few steps due to the effect of the external disturbance to the watch. It is therefore necessary to resynchronise the position of the hour and minute hands. Thus, as part of this function, the control unit 7 can generate a visual message depending on this position, signalling this loss of precision by controlling/driving one or more second light sources 4b.

Other functions of the watch using the determination of the position of at least one hand thereof, can provide for the detection of the number of passes of a hand 24a, 24b above the detecting element 23, for example each pass of the minute hand 24b lights up a second light source 4b, for example a light source facing an index, with the aim of providing rudimentarily timing a certain lapse of time. Start/stop/reset can be achieved by covering the crystal. This variation in brightness is interpreted by the control unit 7 (via the light-detecting element 23 or by the sudden absence of energy production in the photovoltaic module 5) as a start/stop/reset signal. In this example, the number of passes of the hour hand 24a can be counted. After a given number of passes, the second light source 4b is switched on to signal that the watch should be serviced. After an additional number of passes, a second colour, or flashing, can indicate that servicing is required.

Another function linked to this determination of the position of at least one hand of the watch can involve participating in the display of the time system by indicating the “Ante Meridiem (acronym AM)” and “Post Meridiem (acronym PM)”. For example, each time the hour hand 24b passes over the detecting element 23, a second light source 4b is switched on and off to indicate the period of day (morning or afternoon).

Another function linked to this determination of the position of at least one watch hand can provide for illuminating the position of or backlighting the hands 24a, 24b (instead of using luminescent material). In the event that low luminosity is detected by the control unit 7 (via the light-detecting element 23 or by the absence of energy production in photovoltaic module 5), various second light sources 4b are switched on to indicate the position of the hands. For example, twelve detecting elements, each placed opposite an index, can detect the position of the two hands with an accuracy of five minutes in this configuration. The absence of any detection of the minute hand indicates that the two hands are superimposed.

Another function linked to this determination of the position of at least one hand of the watch, can provide for counting the number of times at least one hand 24a, 24b passes, making it possible, for example, to determine the actual operating time of this watch 1, for example between two servicing or maintenance operations for this watch.

It goes without saying that this invention is not limited to the embodiments described above and that various simple alternatives and modifications can be considered by a person skilled in the art without leaving the scope of the invention as defined by the accompanying claims.

1. A dial of a watch comprising a device for determining the position of at least one hand of this watch, such a dial comprising a visible face and a hidden face, said dial being formed by a stack of thin layers of material extending between these two faces, each of said layers comprising one or more of the functional elements included in said determination device:
at least one light-detecting element,
at least a first light source and at least a second light source,
a stand-alone power supply unit comprising a photovoltaic module, and
a control unit for managing the operation of each light source and of said at least one light-detecting element.

2. The dial according to claim 1, comprising a through-hole configured to receive an arbor intended to carry said at least one hand of the watch.

3. The dial according to claim 1, wherein the stack of thin layers of material consists of a first layer provided with the visible face of the dial, and the first layer comprising said at least one light-detecting element and the first and second light sources.

4. The dial according to claim 1, wherein the stack of thin layers includes a second layer comprising the photovoltaic module.

5. The dial according to claim 1, wherein said at least one first light source and said at least one light-detecting element are arranged so that a light beam emitted by said at least one first light source is reflected by said at least one hand towards said at least one light-detecting element.

6. The dial according to claim 1, wherein said at least one first light source is configured to emit a light beam towards a reflective area of said at least one hand, said reflective area being configured to reflect this light beam towards said at least one light-detecting element.

7. The dial according to claim 1, wherein said at least one first light source is configured to emit a light beam towards a reflective area of said at least one hand, said reflective area being configured to reflect this light beam towards said at least one light-detecting element, the reflective area comprising an inclined reflective surface which is formed in a lower face of said at least one hand.

8. The dial according to claim 1, wherein said at least one first light source is configured to emit a light beam towards a reflective area of said at least one hand, said reflective area being configured to reflect this light beam towards said at least one light-detecting element, the reflective area comprising a diffraction grating formed in a lower face of said at least one hand, said grating being configured to reflect a light beam towards said at least one light-detecting element.

9. The dial according to claim 1, wherein said at least one first light source is a vertical-cavity surface-emitting laser source.

10. The dial according to claim 1, wherein said at least one second light source is capable of generating a visual message according to the determined position of said at least one hand.

11. The dial according to claim 1, wherein said first layer is configured such that light radiation, in particular solar radiation and light radiation emitted by the first and second light sources, can fully or partially pass therethrough.

12. The dial according to claim 1, wherein the second layer comprises a substrate on which the photovoltaic module is printed.

13. The dial according to claim 1, wherein said photovoltaic module is arranged on an active area of said second layer, said area being configured to receive light rays originating from the first layer of the stack of thin layers.

14. The dial according to claim 1, wherein the stack of thin layers includes a third layer comprising an electrical energy accumulator constituting the stand-alone power supply unit.

15. The dial according to the claim 1, wherein the stack of thin layers includes a third layer comprising an electrical energy accumulator constituting the stand-alone power supply unit, the third layer comprising a substrate on which the electrical energy accumulator is printed.

16. The dial according to claim 1, wherein the stack of thin layers comprises a fourth layer forming the hidden face of the dial comprising the control unit.

17. The dial according to claim 1, wherein the stack of thin layers comprises a third layer comprising the hidden face of the dial comprising the control unit and an electrical energy accumulator constituting the stand-alone power supply unit.

18. The dial according to claim 1, wherein the first layer is rigid compared to the other layers in the stack, which are flexible.

19. A watch comprising a dial according to claim 1.

20. The watch according to claim 19, comprising a mechanical or electromechanical horological movement.
